(19) United States
(12) Patent Application Publication
(10) Pub. No.: US 2023/0326258 A1
(43) Pub. Date: Oct. 12, 2023

(54) METHOD FOR PREVENTIVE MAINTENANCE OF HMI CONTROLS COMPONENTS

(71) Applicant: VOLVO TRUCK CORPORATION, Göteborg (SE)

(72) Inventors: David DE BRITO, Charvieu Chavagneux (FR); Frédéric BALAIN, Saint Clair Du Rhone (FR)

(73) Assignee: VOLVO TRUCK CORPORATION, Göteborg (SE)

(21) Appl. No.: 18/298,636

(22) Filed: Apr. 11, 2023

(30) Foreign Application Priority Data
Apr. 11, 2022 (EP) 22167529.1

(51) Int. Cl. G07C 5/00; B60W 50/14

(52) U.S. Cl. CPC G07C 5/006; B60W 50/14; B60W 2050/146

(57) ABSTRACT

A method to determine a state of health of an electrical control component of a vehicle, the electrical control component comprising at least two electrical contacts, the at least two electrical contacts being configured to be in a closed status when the electrical control component is activated, or in an open status when the electrical control component is not activated. The electrical component further comprising at least one sensor configured to determine if the status of at least two contacts is open or closed, the method being implemented by an electronic control unit determining, via the at least one sensor, that the status of one of at least two contacts is closed and that another one of at least two contacts is open; incrementing a value of a first counter; determining a first state of health of the electrical control component based on the value of the first counter.

### TECHNICAL FIELD

The invention relates to a method for preventive maintenance to predict the wearing of Human Machine Interface (HMI) controls components like switches (push buttons, rotary switch, toggle switch, mono or bi-stable switches), levers, freewheels, or other kind of HMI interfaces.

The invention can be applied to HMI controls components in any vehicle comprising a Human Machine Interface, including cars, trucks, buses, military vehicles, tramways, trains, boats, aircrafts, etc. . . . . Although the invention will be described with respect to a switch, the invention is not restricted to this particular type of control components, but may also be used for levers, freewheels, or other kind of HMI interfaces.

### BACKGROUND

The technical field of this invention relate to the following context:
HMI controls components like switches (push buttons, rotary switch, toggle switch, mono or bi-stable switches), levers, freewheels or other kind of HMI interfaces;
An electronic architecture with Electronic Control Units (ECUs) communicating via LIN bus or CAN bus or hardwired connection and receiving information from HMI controls components;
An instrument cluster displaying information related to preventive maintenance;
An off board system (fleet management) receiving logged data from trucks and scheduling specific HMI controls components replacement.

Each technology of HMI controls listed above has its own mechanical behaviour and wearing profile.

Some of the HMI components have important and/or safety functions, like the StartStop button, AutoHold or ESP, and the aim of this invention is to be able to predict the end of life of such components and inform the customer or fleet manager to replace it before unplanned stop or safety situation occurs.

Some key factor that we are able to collect to detect the wearing or degradation of internal mechanism of HMI controls switches:
Number of actuations;
loss of redundant contacts;
degradation of contact resistance value.

The preventive maintenance function is aiming to collect data and log them into ECU memory and build warnings and replacement strategies adapted to each features.

Today the switches are designed for a specific reliability depending on several variables like:
number of actuations,
environmental behaviour (temperature, humidity, vibration)
strength to activate switch
electrical and EMC characteristics

. . .

But in real life, today we have no way to monitor the real ageing of this HMI controls. Depending on truck usage, each switch can be used in a different way, and each wearing variable can vary from one customer to another.

For example, A Start&Stop Button is designed for a specific number of pushes, and after this limit, we cannot warranty the correct behaviour of the switch, but this switch is involved in a safety function (start the engine) and then cannot fail (ex if we stall on a railroad crossing, it is mandatory to restart the vehicle quickly).

Today, the driver can inform the switch malfunction to the workshop when it is already failing, but he is not able to verify it nor to predict it.

The invention proposed in this document applies to the preventive maintenance function. The invention will allow us to predict the wearing of switches thanks to logs and then build a strategy to warn the customer or fleet manager and advice for replacement for each individual HMI controls components in the truck, bus, or construction equipment.

### SUMMARY

An object of the invention is to provide a method for preventive maintenance of HMI controls components, which method is configured to predict the wearing of such controls components.

The object is achieved by a method to determine a state of health of an electrical control component of a vehicle, the electrical control component comprising at least two electrical contacts, the at least two electrical contacts being configured to be in a closed status when the electrical control component is activated, or in an open status when the electrical control component is not activated, the electrical component further comprising at least one sensor configured to determine if the status of at least two contacts is open or closed, the method being implemented by an electronic control unit and characterized by the steps of:
determining, via the at least one sensor, that the status of one of at least two contacts is closed and that another one of at least two contacts is open;
incrementing a value of a first counter;
determining a first state of health of the electrical control component based on the value of the first counter.

According to these provisions, the advantage is that the state of health of the electrical control component is monitored.

According to one embodiment, the steps are repeated at successive instants of time during a period of time, and the first state of health is based on the value of the first counter and on a duration of the period of time.

According to these provisions, the advantage is that the monitoring of the state of health takes into account a frequency of occurrence of the event determined at the step of determining.

According to one embodiment, the at least one sensor is further configured to measure a resistance of at least two electrical contacts, the method being further characterized by the further steps of:
measuring, via at least one sensor, the resistance of at least two electrical contacts, at successive instants of time;
determining an evolution over time of the resistance measured;
determining a second state of health of the control component based on the evolution over time of the resistance measured.

According to these provisions, the advantage is that the state of health of the electrical control component is better monitored, according to a second aspect.

According to one embodiment, at least one sensor is further configured to measure a strength applied by a user on the control component to activate the control component, the method being further characterized by the further steps of:
measuring, via at least one sensor, the strength applied by the user on the control component to activate the control component at a number of successive instants of time;
determining a third state of health of the control component based on the strength measured at successive instants of time.

According to these provisions, the advantage is that the state of health of the electrical control component is better monitored, according to a third aspect.

According to one embodiment, at least one sensor is further configured to determine whether the control component is activated, the method being further characterized by the further steps of:
determining, via at least one sensor, that the control component is activated;
incrementing a value of a second counter;
determining a fourth state of health of the control component based on the value of the second counter.

According to these provisions, the advantage is that the state of health of the electrical control component is better monitored, according to a fourth aspect.

According to one embodiment, the method being further characterized by the further step of determining a fifth state of health based on at least one of the first state of health, the second state of health, the third state of health, and the fourth state of health.

According to these provisions, the advantage is that the state of health of the electrical control component is better monitored, according to a combination of different aspects.

According to one embodiment, the method being further characterized by the further step of:
comparing one of the first state of health, the second state of health, the third state of health, the fourth state of health, the fifth state of health, with a pre-warning threshold, to obtain a first comparison result;
trigger a first level action, the step of triggering a first level action being conditioned by the first comparison result.

According to these provisions, the advantage is that the state of health of the electrical control component is planned to be restored.

According to one embodiment, the method is further characterized by the further step of:
comparing one of the first state of health, the second state of health, the third state of health, the fourth state of health, the fifth state of health, with a critical warning threshold, to obtain a second comparison result;
trigger a second level action, the step of triggering a second level action being conditioned by the second comparison result.

According to these provisions, the advantage is that the state of health of the electrical control component is restored immediately.

According to one embodiment, the evolution over time of the resistance measured is a time derivation of the resistance measured, said time derivation being compared with a time derivation threshold to obtain a third comparison result, the step of triggering the second level action being conditioned by the third comparison result.

According to one embodiment, wherein the strength measured is compared to a pre-warning strength threshold, to obtain a fourth comparison result, and wherein the strength measured is compared to a critical warning strength threshold to obtain a fifth comparison result, the step of triggering the first level action being conditioned by the fourth comparison result, and the step of triggering the second level action being conditioned by the fifth comparison result.

According to one embodiment, when the condition for triggering the first level of action is realised at the number of successive instants of time, the number of successive instants of time being greater than a first predetermined number, the step of triggering the first level of action is implemented, and/or when said strength measured is greater than the critical strength threshold, and when the condition for triggering the second level of action is realised at the number of successive instants of time, the number of successive instants of time being greater than a second predetermined number, the step of triggering the second level of action is implemented.

According to one embodiment, the first level action is at least one of display a pre-warning alert on a display device for a driver of the vehicle, send a pre-warning alert to a fleet manager to schedule maintenance of the electrical control component.

According to one embodiment, the second level action is at least one of display a critical-warning alert on a display device for a driver of the vehicle, send a critical-warning alert to a fleet manager to have the electrical control component repaired immediately.

According to an embodiment, a nominal fifth state of health has a value of 100%, and the pre-warning threshold has a value comprised between 15% and 25%, preferably a value of 20%.

According to an embodiment, the critical-warning threshold has a value comprised between 5% and 15%, preferably a value of 10%.

According to other aspects of the invention, the object is achieved by a computer program according to claim 14, and by a computer readable medium according to claim 15, and by an electronic control unit according to claim 16.

Further advantages and advantageous features of the invention are disclosed in the following description and in the dependent claims.

### BRIEF DESCRIPTION OF THE DRAWINGS

With reference to the appended drawings, below follows a more detailed description of embodiments of the invention cited as examples.

In the drawings:

FIG. 1 is a schematic representation of an electrical control component for which its state of health is monitored by an electronic control unit implementing an embodiment of the invention.

FIG. 2 is a graphical representation of an evolution over time of an electrical resistance of a contact of the electrical control component.

FIG. 3 is schematic representation of the sequence of steps of an embodiment of the method according invention.

### DETAILED DESCRIPTION OF EXAMPLE EMBODIMENTS OF THE INVENTION

It is to be understood that the present invention is not limited to the embodiments described above and illustrated in the drawings; rather, the skilled person will recognize that many changes and modifications may be made within the scope of the appended claims.

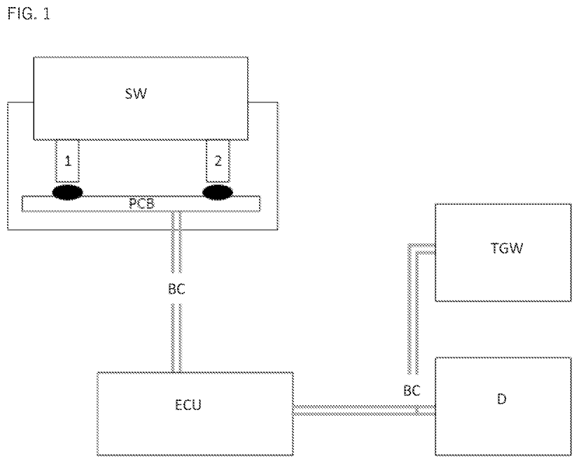

The method is based on several ways to predict the end of life of an electrical control component SW, such as a switch for example as illustrated by FIG. 1, based on:
1) Logging the number of activations compare to a theoretical value sent by the supplier; and/or
2) detect when one of the internal electronic contacts is failing; and/or,
3) measure the contact resistance value of each switch and compare it to a theoretical curve sent by the supplier; and/or,
4) measure the strength needed to activate the switch which will increase along the switch is ageing and compare it to a theoretical value.

Although the invention will be described with respect to a switch SW, the invention is not restricted to this particular type of control components, but may also be used for levers, freewheels, or other kind of HMI interfaces

The different ways, or cases above, are monitored in an ECU and when one of the cases above is triggered, or a combination of them, then the preventive maintenance function will activate its pre-defined strategy depending on estimated wearing levels.

The different cases above will be explained in reference to FIG. 1 representing a push switch SW, configured to be pushed to establish a contact at two terminals 1, 2 of the switch with two corresponding poles on a printed circuit board PCB, the printed circuit board PCB being connected, via a communication bus BC, to an Electronic Control Unit ECU, the Electronic Control Unit ECU being itself connected, via the communication bus BC, to a display D and to another equipment, typically Telematic Gateway (TGW) configured to communicate with a fleet management operator.

In Case 1 above, each activation of the push switch PS is detected and logged into a counter in the Electronic Control Unit ECU memory. Initially the switch state of health is considered equal to 100%, as long as the counter increase, it makes the state of health decreasing. The switch state of health will then reach 0% when the theoretical lifetime value sent by the supplier is exceeded.

In Case 2 above, when the push switch PS may have more than one internal contact, as is the case of the push switch PS of FIG. 1, which has two contacts 1, 2, either because of the mechanical structure of the switch or because of redundancy needs. Each contact is sending the information to the Electronic Control Unit ECU. When the Electronic Control Unit ECU detects that 1 contact is closed but not the other ones, then it is considered as failing. Each time that this phenomena is triggered the switch state of health is reduced by a 5% for example and if it is occurring too often in a period of time (example 3 times in a day) then the switch state of health will automatically be reduced below the critical warning thresholds because we can consider that the end of life is very close.

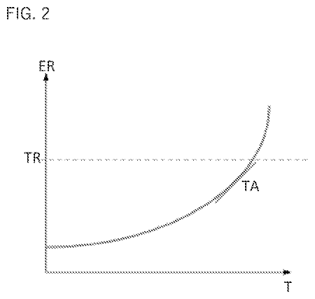

In Case 3 above, thanks to some internal sensors inside the push switch PS it is possible to measure the electrical contact resistance ER of each mechanical contacts. This measurement value can be compared over time and when a significant increase is observed, it corresponds to a close end of life of the switch and then the switch state of health will be automatically decreased under the critical warning thresholds because we can consider that the end of life is very close. For example, as illustrated on FIG. 2, based on a curve representing the nominal evolution of the electrical resistance ER in ordinates over time T in abscissa, a threshold TR on the value of the electrical resistance ER is determined based on the tangent TA of the curve, so that when the electrical resistance ER becomes higher than the determined threshold TR, the switch state of health will be automatically decreased under the critical warning thresholds because it is considered that the end of life is very close.

In case 4 above, thanks to some other internal sensors inside the push switch PS, it is possible to measure the strength applied by the driver when he pushes the button. Then the strength evolution (to activate the switch) may be compared over time. This measurement value may be compared over time and when it exceeds certain predefined values (2 values corresponding to pre-warning or critical warning) over time (typically stable strength over 10 activation), then the switch state of health will be automatically decreased under the pre-warning or critical warning thresholds (corresponding to the strength measured).

Preventive maintenance according to the invention defines 3 levels strategy:
1) Normal: Switch state of health>pre-warning value: no actions needed, the switch is considered to be fully functional
2) Prewarning: pre warning value>=Switch state of health>critical warning value; then a pre-warning alert is displayed in the instrument cluster and sent to fleet manager to schedule maintenance
3) Critical warning: critical warning>=Switch state of health; then a critical alert is displayed in the instrument cluster and sent to fleet manager to go to workshop immediately

In this strategy, the initial switch state of health is considered 100%, a prewarning level may be 20%, a critical level can be 10%. Each threshold can be set individually depending on switch technology and corresponding feature risk levels.

It is also possible to communicate the estimated remaining percentage of life for each switch via telematics TGW to a fleet management system (or for gold contract maintenance) and give a global overview of upcoming maintenance needed.

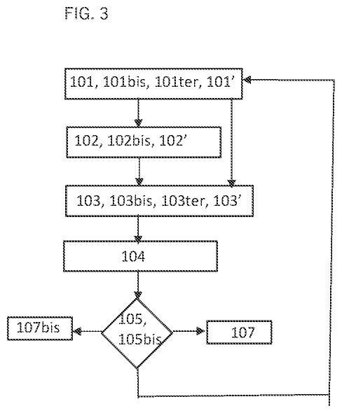

In reference to FIG. 3 the different steps of an embodiment of the method 100 to determine a state of health of the electrical control component SW of a vehicle, is described herein after; the electrical control component SW comprises at least two electrical contacts 1,2, the at least two electrical contacts 1,2 being configured to be in a closed status when the electrical control component SW is activated, or in an open status when the electrical control component SW is not activated, the electrical component further comprises at least one sensor configured to determine if the status of the at least two contacts is open or closed; the method 100 is implemented by an electronic control unit ECU and is characterized by the steps of:
determining 101, via at least one sensor, that the status of one of at least two contacts 1, 2 is closed and that another one of at least two contacts (1, 2) is open;
incrementing 102 a value of a first counter;
determining 103 a first state of health of the electrical control component (SW) based on the value of the first counter;

In particular, the steps are repeated at successive instants of time during a period of time, and wherein the first state of health is based on the value of the first counter and on a duration of the period of time.

In a second example of implementation of the method 100, the at least one sensor is further configured to measure a resistance of at least two electrical contacts, the method 100 being further characterized by the further steps of:
measuring 101bis, via the at least one sensor, the resistance of the at least two electrical contacts, at successive instants of time;
determining 102bis an evolution over time of the resistance measured;
determining 103bis a second state of health of the control component based on the evolution over time of the resistance measured.

In a third example of implementation of the method 100, the at least one sensor is further configured to measure a strength applied by a user on the control component to activate the control component, the method being further characterized by the further steps of:
measuring 101ter, via the at least one sensor, the strength applied by the user on the control component to activate the control component at a number of successive instants of time;
determining 103ter a third state of health of the control component based on the strength measured at successive instants of time.

In a fourth example of implementation of the method 100, the at least one sensor is further configured to determine whether the control component is activated, the method being further characterized by the further steps of:
determining 101′, via the at least one sensor, that the control component is activated;
incrementing 102′ a value of a second counter;
determining 103′ a fourth state of health of the control component based on the value of the second counter.

More particularly, the method 100 comprises a further step of determining 104 a fifth state of health based on at least one of the first state of health, the second state of health, the third state of health, and the fourth state of health. Thus, the fifth state of health may be a combination of any two or more of the first state of health, the second state of health, the third state of health, and the fourth state of health.

Even more particularly, the method 100 being further characterized by the further steps of:
comparing 105 the fifth state of health with a pre-warning threshold and with a critical warning threshold;
if 106 the fifth state of health is comprised between the pre-warning threshold and the critical warning threshold, trigger 107 a first level action;
if 106 the fifth state of health is greater than the critical warning threshold, trigger 107bis a second level action.

Optionally, the evolution over time of the resistance measured at step 102bis is a time derivation of the resistance measured, said time derivation being compared with a time derivation threshold, so that when said time derivation is greater than the time derivation threshold the second state of health is set to a value under the critical warning threshold.

According to a further option, the strength measured at step 101ter is compared to a pre-warning strength threshold and to a critical warning strength threshold, so that when said strength measured is comprised between the pre-alert strength threshold and the critical strength threshold, the third state of health is set to a value under the pre-alert warning threshold, and when said strength measured is greater than the critical strength threshold, then the third state of health is set to a value under the critical warning threshold.

More specifically, the strength measured at step 101ter at the number of successive instants of time is successively compared to a pre-warning strength threshold and to a critical warning strength threshold, so that when said strength measured is successively comprised between the pre-alert strength threshold and the critical strength threshold, and when the number of successive instants of time is greater than a predetermined number, the third state of health is set to a value under the pre-alert warning threshold, and when said strength measured is greater than the critical strength threshold, and when the number of successive instants of time is greater than the predetermined number, then the third state of health is set to a value under the critical warning threshold.

For example, the first level action 107 is the action of displaying a pre-warning alert on a display device D for a driver of the vehicle, or sending a pre-warning alert to a fleet manager TGW to schedule maintenance of the electrical control component SW. The second level action 107bis is at least one of display a critical-warning alert on a display device D for a driver of the vehicle, send a critical-warning alert to a fleet manager TGW to have the electrical control component SW repaired immediately.

In particular, a nominal fifth state of health has a value of 100%, and the pre-warning threshold has a value comprised between 15% and 25%, preferably a value of 20%; the critical-warning threshold has a value comprised between 5% and 15%, preferably a value of 10%.

According to an aspect, the invention also relates to a computer program comprising program code means for performing the steps described herein above when said program is run on a computer.

According to a further aspect, the invention also relates to a computer readable medium carrying a computer program comprising program code means for performing the steps described herein above when said program product is run on a computer.

According to another aspect, the invention also relates to an electronic control unit ECU for controlling a state of health of an electrical control component SW of a vehicle, the electronic control unit ECU being configured to perform the steps of the method 100 described herein above.

1. A method to determine a state of health of an electrical control component of a vehicle, the electrical control component comprising at least two electrical contacts, the at least two electrical contacts being configured to be in a closed status when the electrical control component is activated, or in an open status when the electrical control component is not activated, the electrical component further comprising at least one sensor configured to determine if the status of at least two contacts is open or closed, the method being implemented by an electronic control unit and characterized by the steps of:
determining, via the at least one sensor, that the status of one of at least two contacts is closed and that another one of at least two contacts is open;
incrementing a value of a first counter;
determining a first state of health of the electrical control component based on the value of the first counter.

2. A method according to claim 1, wherein the steps are repeated at successive instants of time during a period of time, and wherein the first state of health is based on the value of the first counter and on a duration of the period of time.

3. A method according to claim 1, wherein the at least one sensor is further configured to measure a resistance of at least two electrical contacts, the method being further characterized by the further steps of:
measuring, via at least one sensor, the resistance of at least two electrical contacts, at successive instants of time;
determining an evolution over time of the resistance measured;
determining a second state of health of the control component based on the evolution over time of the resistance measured.

4. A method according to claim 1, wherein at least one sensor is further configured to measure a strength applied by a user on the control component to activate the control component, the method being further characterized by the further steps of:
measuring, via at least one sensor, the strength applied by the user on the control component to activate the control component at a number of successive instants of time;
determining a third state of health of the control component based on the strength measured at successive instants of time.

5. A method according to claim 1, wherein at least one sensor is further configured to determine whether the control component is activated, the method being further characterized by the further steps of:
determining, via at least one sensor, that the control component is activated;
incrementing a value of a second counter;
determining a fourth state of health of the control component based on the value of the second counter.

6. A method according to claim 1, the method being further characterized by the further step of determining a fifth state of health based on at least one of the first state of health, the second state of health, the third state of health, and the fourth state of health.

7. A method according to claim 1, the method being further characterized by the further step of:
comparing one of the first state of health, the second state of health, the third state of health, the fourth state of health, the fifth state of health, with a pre-warning threshold, to obtain a first comparison result;
trigger a first level action, the step of triggering a first level action being conditioned by the first comparison result.

8. A method according to claim 7, the method being further characterized by the further step of:
comparing one of the first state of health, the second state of health, the third state of health, the fourth state of health, the fifth state of health, with a critical warning threshold, to obtain a second comparison result;
trigger a second level action, the step of triggering a second level action being conditioned by the second comparison result.

9. A method according to claim 8, wherein the evolution over time of the resistance measured is a time derivation of the resistance measured, said time derivation being compared with a time derivation threshold to obtain a third comparison result, the step of triggering the second level action being conditioned by the third comparison result.

10. A method according to claim 7, wherein the strength measured is compared to a pre-warning strength threshold, to obtain a fourth comparison result, and wherein the strength measured is compared to a critical warning strength threshold to obtain a fifth comparison result, the step of triggering the first level action being conditioned by the fourth comparison result, and the step of triggering the second level action being conditioned by the fifth comparison result.

11. A method according to claim 10, wherein when the condition for triggering the first level of action is realised at the number of successive instants of time, the number of successive instants of time being greater than a first predetermined number, the step of triggering the first level of action is implemented, and/or when said strength measured is greater than the critical strength threshold, and when the condition for triggering the second level of action is realised at the number of successive instants of time, the number of successive instants of time being greater than a second predetermined number, the step of triggering the second level of action is implemented.

12. A method according to claim 7, wherein the first level action is at least one of display a pre-warning alert on a display device for a driver of the vehicle, send a pre-warning alert to a fleet manager to schedule maintenance of the electrical control component.

13. A method according to claim 8, wherein the second level action is at least one of display a critical-warning alert on a display device for a driver of the vehicle, send a critical-warning alert to a fleet manager to have the electrical control component repaired immediately.

14. A computer program comprising program code for performing the steps of claim 1 when said program code is run on a computer.

15. A non-transitory computer readable medium carrying a computer program comprising program code for performing the steps of claim 1 when said program code is run on a computer.

16. An electronic control unit for controlling a state of health of an electrical control component of a vehicle, the electronic control unit being configured to perform the steps of the method according to claim 1.
